(19) United States
(12) Patent Application Publication
(10) Pub. No.: US 2018/0213975 A1
(43) Pub. Date: Aug. 2, 2018

(54) COOKER WITH THERMOELECTRIC GENERATION

(71) Applicant: Terraoak, Inc., Waverly, IA (US)

(72) Inventors: Maxwell K. Chinnah, Waverly, IA (US); Godwin Attigah, Hillside, NJ (US)

(21) Appl. No.: 15/934,641

(22) Filed: Mar. 23, 2018

Related U.S. Application Data
(63) Continuation of application No. PCT/US17/19144, filed on Feb. 23, 2017.
Application No. PCT/US17/19144 is a continuation-in-part of application No. 15/051,485, filed on Feb. 23, 2016, now Pat. No. 9,955,819.

(51) Int. Cl. A47J 37/07; H01L 35/10; H01L 35/30; H01L 35/32; H01L 35/34

(52) U.S. Cl. CPC A47J 37/0763; H01L 35/10; H01L 35/34; H01L 35/32; H01L 35/30

(57) ABSTRACT

A combustion cooker with an integrated and optionally removable thermoelectric generator and methods for making and using the same. The combustion cooker can include a fire basket that comprises a bottom region and a lateral region that is coupled with the bottom region and that defines a central combustion chamber. Being disposed about a periphery of the fire basket, the thermoelectric generator can include a cold side heat sink and a hot side heat sink. The cold side heat sink can be cooled via exterior air available outside the housing; whereas, the hot side heat sink can be in direct thermal communication with the periphery of the fire basket. Thereby, the thermoelectric generator advantageously can generate electrical power based upon a thermal differential between the cold side heat sink and the hot side heat sink.

### CROSS-REFERENCE TO RELATED APPLICATIONS

This application is a continuation of, and claims priority to, PCT Patent Application No. PCT/US2017/019144, which was filed on Feb. 23, 2017, which claims the benefit of, and priority to, copending U.S. patent application Ser. No. 15/051,485, filed on Feb. 23, 2016. Priority to the above-identified patent applications is expressly claimed, and the disclosures of the applications are hereby incorporated herein by reference in their entireties and for all purposes.

### BACKGROUND

Portable combustion cookers and heaters are well known and widely used, particularly in developing countries as a primary means of food preparation and by campers and others who lack more elaborate cooking facilities. These devices operate to burn a hydrocarbon-based fuel source and direct the resultant heat onto a cooking vessel. The most versatile cookers are those that are capable of burning a variety of biomass fuels which are often more readily available than petroleum-based fuel sources such as liquefied or gaseous petroleum products such as kerosene, methane, natural gas, heating oil, and the like. Many portable combustion cookers are inefficient and highly polluting. Inefficient combustion results in the production of high levels of soot, smoke, and other airborne particulates and pollutants, and inefficient heating of the cooking vessel causing a concomitant increase in fuel consumption.

Access to electricity in camping and emergency situations, and in developing countries, is often sporadic, unreliable, or entirely unavailable. Accordingly, combustion cookers have been designed that convert a portion of the combustion heat into electricity using a thermoelectric generator (“TEG”). See, for example, U.S. Pat. No. 8,297,271, U.S. Pat. No. 8,861,062, and U.S. 2015/0201805. A heat sink element (e.g., a metal or other thermal conductor) transfers heat from the combustion chamber to the TEG for electricity production. However, there is a need to provide combination cooker/generator devices that are portable, inexpensive to produce, energy efficient, and environmentally friendly, while retaining the versatility of mixed biomass fuel cooker.

### SUMMARY OF THE INVENTION

The invention provides a combustion device and, more specifically, a cooker configured to burn a hydrocarbon-based fuel (e.g., biomass and liquid petroleum products). Generally, the combustion device is defined by an outer housing, an inner housing disposed within the outer housing, wherein the space between the inner housing and outer housing defines an air gap, a fire basket comprising perforations and defining a combustion chamber disposed within the inner housing, at least one (e.g., one, two, three, four, or more) thermoelectric generator comprising an electricity output interface, and an electric fan adapted to force air into the fire basket either directly or from the air gap and through perforations in the inner housing.

In one configuration, the invention provides a combustion device having an outer housing, an inner housing disposed within the outer housing, wherein the space between the inner housing and outer housing defines an air gap, a fire basket comprising perforations and defining a combustion chamber disposed within the inner housing, a thermoelectric generator comprising a hot side heat sink and a cold side heat sink, wherein the hot side heat sink is in thermal communication with the fire basket and the cold side heat sink is open to exterior directly or through an air flow path, and an electric fan powered by the thermoelectric generator and adapted to force air into the fire basket.

In some embodiments, the inner housing has perforations including, for example, within the lower half of the inner housing. In other embodiments, the fire basket comprises a wire mesh of one, two, three, or more layers and, optionally, may comprise a catalytic material (e.g., metal).

In some embodiments, the electric fan is adapted to force air directly into the fire basket. In other embodiments, the fan is adapted to force air into the air gap in a manner that causes the air to then be forced into the fire basket (e.g., through perforations in the inner housing).

In another configuration, invention provides a combustion device (cooker) configured to burn a hydrocarbon-based fuel (e.g., biomass and liquid petroleum products). Generally, the combustion device is defined by an outer housing having a first opening, an inner housing having a second opening and disposed within the outer housing, wherein the space between the inner housing and outer housing defines an air gap, a fire basket comprising perforations and defining a combustion chamber disposed within the inner housing, and a thermoelectric generator disposed within the first opening and the second opening and comprising a hot side heat sink, a cold side heat sink, an electricity output interface, an air flow path defined by an intake port open to exterior of the combustion device and an exhaust port open to the air gap, wherein the air flow path is in communication with the cold side heat sink, and an electric fan powered by the thermoelectric generator and adapted to draw air through the air flow path.

In some embodiments, the hot side heat sink is disposed within the inner housing, is thermally coupled to the fire basket, or is disposed within the fire basket.

In some embodiments, the inner housing further comprises perforations. Optionally, the perforations are contained within the lower half of the inner housing, preferably at a level below the bottom of the fire basket.

In some embodiments, the fire basket has perforations that define at least 25%, 50%, 75% or more of the surface area of the fire basket. Optionally, the fire basket is formed from a wire mesh. The fire basket may have one, two, three, or more layers (e.g., of wire mesh). Optionally, a catalytic material is incorporated into the fire basket. The catalytic material may be provided as a coating on at least one layer of the fire basket or it may be provided as a discrete layer, such as a discrete mesh layer.

In some embodiments, the outer housing may be open at the bottom or have a solid or discontinuous bottom. Optionally, the outer housing has perforations (e.g., in a solid bottom or lateral sides). Preferably, the perforations, if present, are located in the lower 25% or lower 50% of the outer housing body. Optionally, the outer housing also contains reversible closures for the perforations such that an operator can regulate the air flow through the perforations when the combustion device is in use.

In other embodiments, the combustion device also contains a ash collection container positioned below the fire basket. Optionally, the outer housing also has an opening, a door, or another reversal closure, aligned with an opening in the inner housing which together are adapted to allow for the placement and removal of the ash container within the combustion device.

Other features and embodiments of the combustion device are set forth in the following description.

As used herein, “perforations” refers to holes or voids in an otherwise solid surface. It is understood that that the perforated surface may contain one or a plurality of holes. In some embodiments the perforations comprise less than 50% of the area of the surface. In other embodiments, perforated surfaces can be formed from a mesh (e.g., a wire mesh), wherein the term “mesh” generally refers to surfaces in which the perforations comprise more than 50% of the area of the surface.

As used herein, “biomass” or “biomass fuel source” means any carbonaceous material suitable for combustion. Biomass that may be used as fuel in the cooker devices of the invention include, but are not limited to, wood, paper, cardboard, coal, oil, and other petroleum products.

As used herein, terms such as “top”, “bottom”, “up”, “down”, and the like refer to directions relative to a cooker 10 having the general configuration shown in FIG. 1, when the cooker 10 is standing in its intended upright position on a substantially horizontal surface.

### BRIEF DESCRIPTION OF THE DRAWINGS

FIG. 1 is a perspective view of an assembled cooker 10 according to the principles and features described herein.

FIG. 2 is a perspective view of an outer housing 100.

FIG. 3 is a perspective view of an inner housing 200.

FIG. 4 is a perspective view of a fire basket 300.

FIG. 5 is a cut-away view illustrating the assembly of a fire basket 300 and inner housing 200.

FIG. 6 is a cut-away view of an assembled cooker 10 illustrating the relative positioning of the various components described herein.

FIG. 7 is a schematic cross-sectional view of an assembled cooker 10.

FIG. 8 is a schematic of a thermoelectric generator 400.

FIG. 9 is a perspective view of an assembled cooker 20 according to the principles and features described herein.

FIG. 10 is a schematic wiring diagram of cooker 20 having multiple TEGs 400.

FIG. 11 is a top plan view of cooker 20.

FIGS. 12A-12B are cross-sectional views of cooker 20.

FIG. 13 is an exploded view of cooker 20.

### DETAILED DESCRIPTION

The invention generally provides a modular biomass-fired combustion cooker with one or more integrated thermoelectric generator (TEG) and components for use therein. In the various configurations, the cooker generally consists of three distinct housing components: an outermost outer housing, an intermediately-disposed inner housing, and an inner fire basket (combustion chamber). Optionally, the fire basket comprises a catalytic material in order to reduce air pollution and certain combustion gases produced by the burning of hydrocarbon-based (e.g., biomass) fuel. The cooker also contains one or more (e.g., one, two, three, four, or more) TEGs which may be in direct or thermally-coupled contact with the fire basket. Optionally, the cooker contains one or more (e.g., one, two, three, four, or more) electric fans that increase the airflow into the fire basket and/or cools the cold side heat sink of the TEG(s). The fan(s) may be powered from an independent power source (e.g., a battery, a solar panel, or power from an electrical grid) or from the TEG(s). Each of the cooker components is described in more detail below.

Outer Housing

The outer housing forms the outermost shell of the cooker. The outer housing provides structural support for other externally-mounted and integral components as described herein and, in combination with the air gap and inner housing, serves as a heat shield. Under normal operating conditions, the lateral sides of the outer housing remain relatively cool, thereby minimizing the chance that a user will accidently burn themselves or that the cooker will ignite flammable materials that are nearby or in contact with the cooker. The outer housing may be continuous (i.e., completely enclose the inner housing) or discontinuous.

The outer housing may have any convenient three-dimensional shape including, for example, a cylindrical/round, ovoid/oval, square, rectangular, etc. The outer housing may be formed from any suitable non-flammable material that is capable of supporting the other cooker elements, as described herein. In order to minimize the weight, expense of manufacture, and to facilitate the ease of manufacture, the outer housing may be formed from rolled or corrugated steel sheeting.

In some embodiments, the outer housing has a venting structure such as a door, removable panel, or vented/perforated structure to facilitate air flow into the air gap between the outer housing and the inner housing. These features are particularly useful in a continuous outer housing but also may be present when the outer housing is discontinuous. Optionally, the venting structure comprises a reversible closure so to allow the user to control the air flow. Optionally, the venting structure includes an electric fan (e.g., a constant-speed or variable-speed fan). The fan may be used to create a positive pressure within air gap by blowing ambient air into the cooker (e.g., the fire basket through various perforations) in order to improve the efficiency of combustion.

Optionally, the outer housing also contains a door positioned at a level below the bottom of the fire basket and is designed to provide access to an ash collection container. Optionally, the outer housing also contains a plurality (three, four, five, six, or more) legs designed to support the outer housing 100 above the ground.

The outer housing may be open at the bottom or it may contain a continuous or discontinuous (e.g., perforated) bottom surface member. An outer housing that is open at the bottom or contains a discontinuous bottom surface member is useful for improving air flow into the combustion chamber. These embodiments are particularly useful in conjunction with legs that raise the bottom of the cooker above the ground. A continuous and solid bottom surface member is useful when it is desired that all ashes and combustion material be retained within the cooker.

Inner Housing

The body of the inner housing is configured to fit within the outer housing and provide an air gap between the inner housing and the outer housing. In some embodiments, the air gap is about 1, 2, 3, 4, 5, 6, 7, 8, 9, 10, or inches wide. Preferably, the inner housing has the same general shape as the outer housing. The shape is not critical and these components may be differently-shaped but still function in accordance with the principles of the invention. Furthermore, there is no need for the inner housing and outer housing to have the same general shape, although it is preferred. For example, the outer housing may be square or rectangular and the inner housing may be round.

The inner housing contains one or more openings configured to accommodate the one or more TEGs. Optionally, the opening in the inner housing and aligns with an opening in the outer housing in order that the TEG may extend through both the inner housing and outer housing, or extend only through the inner housing but be exposed to the exterior through the opening in the outer housing. The opening in the outer housing may be an opening through a continuous portion of the outer housing itself or in a gap created as a result of a discontinuous outer housing. The TEG should be accessible to facilitate servicing, removal, and operation including providing access to the power outlets.

Optionally, the outer housing and the inner housing have an alignment mechanism to assist in aligning the optional openings and/or facilitate the proper alignment and mating of the inner housing with the outer housing when the cooker is assembled. An alignment mechanism may be, for example, a tab-and-channel system in which the inner wall of the outer housing contains one alignment member that may be reversibly engaged with the other alignment member on the outer wall of the inner housing. Alternatively, the outer housing, or panels of a discontinuous outer housing, have mating pair members that are matched on the inner housing to facilitate alignment, assembly, and for reversibly or permanently joining the various components together.

Optionally, the cooker contains one or more fans that increase airflow within the gap created between the inner housing and the outer housing. The fan(s) may be powered from a TEG or from an independent power source. The fans may be mounted on the inner housing or outer housing, as is convenient. The purpose of increasing the air flow within the air gap is to improve the efficiency of combustion by forcing more air into the combustion chamber.

Optionally, the inner housing also has an opening which aligns with door or other opening in the outer housing to provide access to an ash collection container.

Optionally, the inner housing also contains perforations that facilitate airflow from the air gap between the inner housing and the outer housing into the combustion chamber defined by the fire basket. There is no limitation on the size, amount, or location of the perforations. However, in order to promote efficient combustion, it is preferred that at least the upper 50% of the inner housing is substantially solid. In another embodiment, the perforations are located below the bottom of the fire basket, when the fire basket is positioned within the inner housing. The solid (unperforated) upper portion of the inner housing functions as a chimney for the heat and combustion gases produced in the combustion chamber. Optionally, the perforations are present adjacent to the lower eighth, quarter, or half of the fire basket. The perforations may extend completely or partially around the body of the inner housing.

Inner housing may comprise a generally horizontal cooker top as an integral member. In this configuration, inner housing is used with an outer housing that is open at the top such that the cooker is defined on the lateral surfaces by the outer housing and top surface by the cooker top. Thus, the bottom side of the cooker top rests on the top edges of the outer housing when the cooker is assembled.

The inner housing also may contain a support structure for the fire basket which is placed therein. The support structure may be a solid bottom, preferably having perforation, capable of supporting the weight of the fire basket and biomass fuel. Alternatively, the support structure may be one or more engagement mechanisms disposed about the interior surface and designed to interact with the fire basket and provide suspension. Alternatively, the fire basket may be self-supporting such as through an integral lip or rim that rests on top of the inner housing and/or the outer housing.

It is understood that the foregoing configuration is not limiting. For example, the cooker top may be provided as a separate element that is reversibly engaged or integral with the outer housing, the inner housing, or the fire basket. In this configuration, the cooker may be assembled by placing the inner housing within the outer housing and securing the two components together using the cooker top. The fire basket may be configured such that it can be inserted through the opening when the other elements are assembled. Alternatively, the fire basket may be placed within the inner housing prior to the addition of the cooker top. This latter configuration has the advantage that it can be adapted to secure the fire basket within the cooker such that the fire basket remains contained within the cooker, even if the unit is knocked over.

In yet another configuration, the cooker top may be contiguous with the fire basket such that the inner housing would be open at the top to accommodate the combined component.

The specific configuration of the cooker top does not alter the cooker's function. The cooker top should be configured to provide a stable surface surrounding chimney opening in the top surface of the cooker and capable of supporting cooking ring and a cooking vessel. Preferably, the cooker top, in any configuration, provides a relatively tight seal between itself and the outer housing and/or the inner housing such that the combustion heat and gases are efficiently and substantially completely vented through chimney opening.

Fire Basket

The fire basket defines the combustion chamber and, when assembled, is disposed within the inner housing. The fire basket should be made of material that can withstand the heat of combustion without deforming and is thermoconductive. Typically, the fire basket is made of metal (e.g., steel, cast iron). The fire basket is configured to be open at the top to allow for loading of fresh biomass for combustion and for the removal of spent biomass fuel (e.g., ashes). The fire basket also is configured to permit efficient and high volume air flow into the combustion chamber. In some embodiments, the fire basket is defined as having lateral sides and a bottom. The lateral sides may be perforated over their entire height or may be perforated only over the bottom quarter, half, or three quarters of their height. The upper unperforated region, if present, serves as the chimney to allow for the efficient escape of hot combustion gases. The bottom may be solid or perforated and is adapted to support the weight of the biomass fuel to be contained therein.

In one embodiment, the fire basket is composed of a mesh in which more than 25%, 50%, 75%, or more of the surface area is defined by the void space of the perforations.

In one embodiment, the lateral sides of the fire basket 300 have an inner and an outer layer. Preferably, both layers are mesh and/or have perforations.

In one embodiment, the fire basket further contains a support mechanism for engaging the inner housing and/or the outer housing. The support mechanism may be a flange configured to rest on the top of the inner and/or outer housing(s) or a support member within the inner housing.

In one embodiment, the fire basket also contains a catalytic metal such as platinum, palladium, rhodium, and gold, to facilitate the oxidation of carbon monoxide and/or the reduction of nitrogen oxides produced during combustion of the biomass. The catalytic metal may be coated on an underlying metal (e.g., steel) substrate (e.g., by electroplating), or provided as a discrete element such as a mesh layer that defines the fire basket.

Ash Collection Container

In some embodiments, the cooker further comprises an ash collection container positioned below the fire basket. An ash collection container is particularly useful with a fire basket having perforations in the bottom surface. An ash collection container is also useful in a cooker in which the outer housing is open at the bottom.

The ash collection container is formed from any suitable material that can withstand the heat of combustion without becoming deformed or damaged. Suitable materials include metals, as described herein. The ash collection container may have any shape and dimension appropriate for retaining the amount of ash expected to be produced based on the volume of the combustion chamber, intended duration of cooker use, and anticipated biomass fuel type.

In one embodiment, the ash collection container is suspended on supports fixed to the inner surface of the inner housing at a level that is below that of the bottom of the fire basket when the fire basket is installed. The ash collection container may be accessed through the chimney portion of the inner housing when the fire basket is removed or through the outer housing when the fire basket and inner housing are removed. Optionally, the ash collection container may be accessed through a door or opening in the outer housing that aligns with an opening in the inner housing. The advantage of this configuration is that there is no requirement for fire basket removal and the ash collection container may be removed and emptied while the cooker is in use.

Thermoelectric Generator

Thermoelectric generators are known to the skilled artisan. TEGs operate on the Seeback effect and convert thermal energy into electricity. The core of the TEG is the thermoelectric module which consists of two different thermoelectric materials (heat carriers) that are electrically interconnected. A thermal gradient between the “hot side” and the “cold side” causes a direct current to flow in the electrical circuit as the heat is transferred through the heat carriers. The amount of electricity produced is proportional to the heat differential across the TEG (i.e., between the hot side and the cold side). Thus, electricity generation depends upon the efficient heating of the hot side and the efficient cooling of the cold side. Electricity produced in the circuit is directed to an output interface. The output interface may be any convention electrical socket or specialized electrical charging adapter such as a USB port.

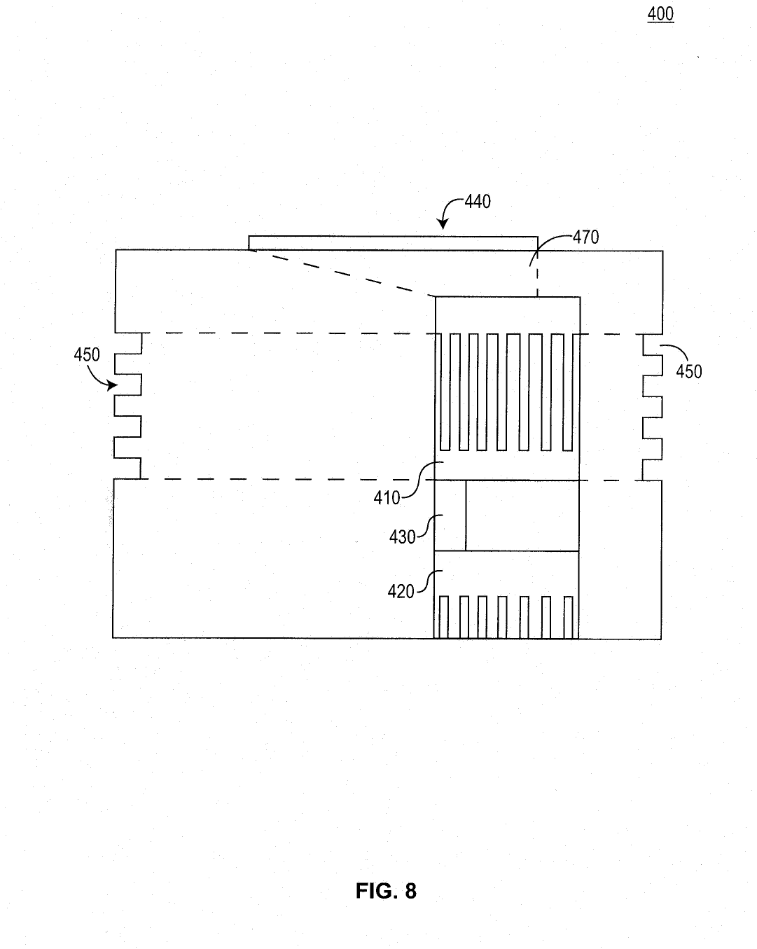

FIG. 8 is a TEG schematic illustrating the cold side heat sink 410, the hot side heat sink 420, and the intervening thermoelectric materials 430. One strategy for maintaining a high thermal gradient is to provide an air flow path across the cold side heat sink 410 in order to provide air cooling. In one embodiment, an electric fan 440 configured to draw or blow ambient (cold) air through an intake port 470 and across the cold side heat sink 410 to more efficiently dissipate heat, thereby maintaining a high thermal gradient. The warmed air is exhausted through one or more exhaust vents 450. In one embodiment, the electric fan 400 draws power from the TEG for operation (i.e., does not require an external power source).

Heat produced in the combustion chamber of the fire basket may be transferred to the hot side by any appropriate method. In one embodiment, a thermally conductive probe is placed in thermal connection with the hot side heat sink 420 and extended into the combustion chamber such that the probe is heated directly by the flame and/or hot air within the combustion chamber. Thermally conductive probes may comprise a metal such as copper and steel. In this embodiment, the TEG may be disposed entirely outside of the outer housing 100 with only the probe penetrating the outer and/or inner housing. Alternatively, or in addition to the probe extending into the combustion chamber, the probe may be in thermally conductive contact with the fire basket. Optionally, the probe extends through an opening in the wall of the fire basket 300 and terminates within the combustion chamber.

In another embodiment, the TEG is positioned such that the hot side heat sink 420 is in direct thermal contact with the fire basket and/or is exposed to the interior of the fire basket. In some embodiments, the TEG is permanently or removably coupled to the fire basket. Direct thermal contact includes placing the hot side heat sink 420 in direct physical contact with the fire basket or providing a physical thermal connection (e.g., copper, steel, or other appropriate metal or thermal conductor) that physically contacts both the hot side heat sink 420 and the fire basket 300. This embodiment differs from an externally-mounted TEG and probe in that the hot side heat sink 420 is disposed within the outer dimension of the outer housing 100 and the thermal connection, if present, merely facilitates contact between the hot side heat sink 420 and the fire basket 300. For example, the thermal connection may be a non-perforated flattened region of the fire basket against which the hot side heat sink 420 rests. In this way, the fire basket 300 efficiently absorbs the heat of combustion by virtue of its large surface area (larger than the probe of the previous embodiment) and transfers that absorbed heat to the hot side heat sink 420. This configuration provides more efficient heat transfer than the previous embodiment utilizing a probe connected to an external TEG because of the larger surface area and mass of the fire basket 300. Additionally, electricity may be produced after all of the biomass fuel is consumed because the fire basket 300 will remain hotter than the air in the combustion chamber.

In another embodiment, the TEG is positioned with the hot side heat sink 420 positioned within the inner housing but not in direct thermal contact with the fire basket. This configuration has the advantage of holding the hot side heat sink 420 in close proximity to the flame and fuel source and results in higher temperature gradients than the first embodiment involving a probe and externally-mounted TEG. Optionally, the hot side heat sink 420 is placed within the fire basket. In this embodiment, the fire basket also has an opening that aligns with the opening in the inner housing and the opening in the outer housing such that the TEG penetrates all three structural elements, thereby positioning the hot side heat sink 420 within the fire basket.

In another embodiment that may be used in conjunction with any of the preceding TEG configurations, the union of the TEG and the outer housing is configured such that the exhaust vents 450 discharge some or all of the warmed air from the cold side heat sink 410 into the air gap 130 between the outer housing 100 and inner housing 200. The air vented into the air gap 130 therefore is forced through the perforations 230 in the inner housing 200 and into the combustion chamber defined by the fire basket 300. Relative to a configuration in which air is passively drawn into the combustion chamber, this configuration provides for a more efficient burn of the biomass fuel resulting in less soot and carbon monoxide production, and achieves higher combustion temperatures which improves cooking time and electricity generation. In this embodiment, it is preferable that the outer housing 100 further contain a solid bottom such that the fan 440 creates a positive air pressure within the air gap, thereby forcing substantially all of the exhausted air through the perforations 230 and into the fire basket 300.

Optionally, the TEG electricity generation circuit is functionally coupled to a rechargeable battery which may be integrated into the TEG or removably connected to the TEG through the output interface. The battery may be used to store electricity generated during cooker use that is not immediately consumed by a device electrically coupled to the output interface 450. Removable batteries either coupled to the output interface 450 or through another electrical coupling to the TEG circuit are preferred because it is often desirable to have an electricity source that is portable and/or available when the cooker is not in use.

In one embodiment, the fan 440 is a variable speed fan that may be controlled by the operator. Increasing the fan speed may increase the combustion temperature by forcing more air into air gap 130, thereby providing more oxygen to the combustion chamber.

The principles and features of the invention are illustrated in the following examples. The examples are not intended to be limited.

### EXAMPLE 1

### Cooker With Continuous Outer Housing And A Single TEG

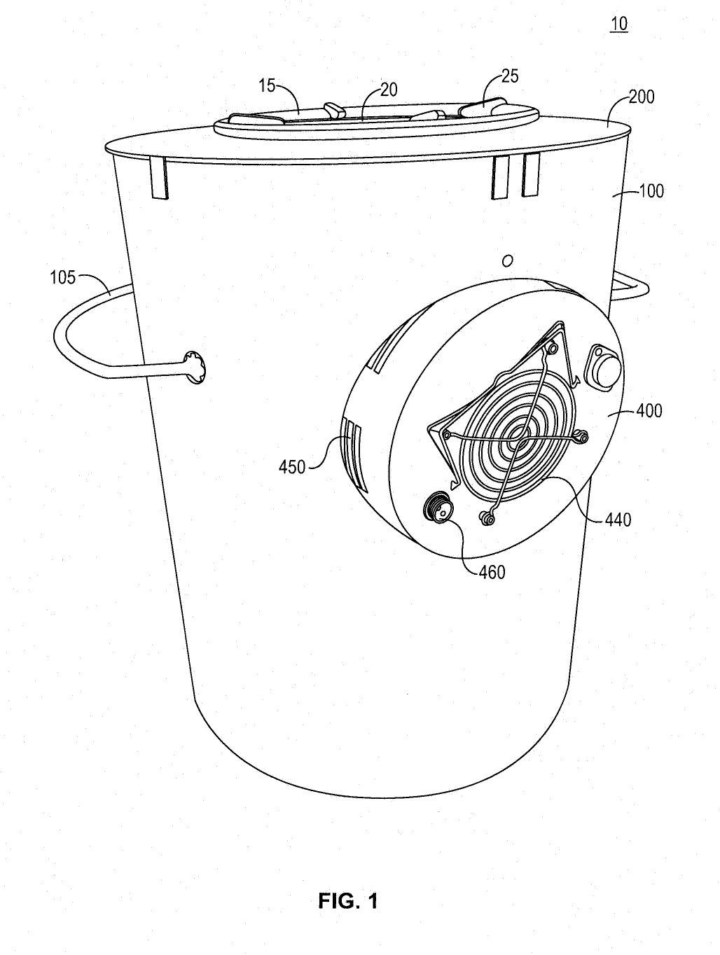

FIG. 1 is a perspective view of a fully assembled cooker 10 constructed in accordance with one embodiment of the invention. The cooker 10 is defined by an outer housing 100, and inner housing 200, and a TEG 400. Optionally, the outer housing 100 contains a handle 105 to aid in moving or carrying the cooker 10. The handle 105 may be fixed and rigid as illustrated, attached to the outer housing 100 by way of a hinge mechanism such that the handle 105 is movable, or removably attached. The specific design of the handle 105 is not limiting and is intended solely for the purpose of moving or carrying the cooker 10. Therefore, the handle(s) must be capable of supporting the weight of the fully-assembled cooker and at least a normal amount of biomass fuel. Although depicted in FIG. 1 as having only a single handle 105, it is understood that the outer housing 100 of the cooker 10 may have two, three, four, or more handles, as necessary and desirable, based on the specific design of the cooker 10 handle 105.

Optionally, the cooker 10 also has a cooking ring 15 that circumnavigates the opening 20 to the combustion chamber. The cooking ring 15 may be integral or attached to the top surface of the cooker 10 (illustrated as the top surface of the inner housing) or it may be provided as a separate component that is positioned around the opening 20. The cooking ring 15 is configured to suspend a cooking vessel above the opening 20 for efficient heating and allow for the venting of combustion gases and heat produced in the combustion chamber. In one embodiment, the cooking ring 15 has one, two, three, four or more tabs 25 that extend into the opening and, optionally, contact the inner surface of the combustion chamber. The tabs 25 are intended to prevent the cooking ring 15 from sliding across the top surface of the cooker 10. The following description further exemplifies the structure and features of the cooker 10 and its components.

Outer Housing

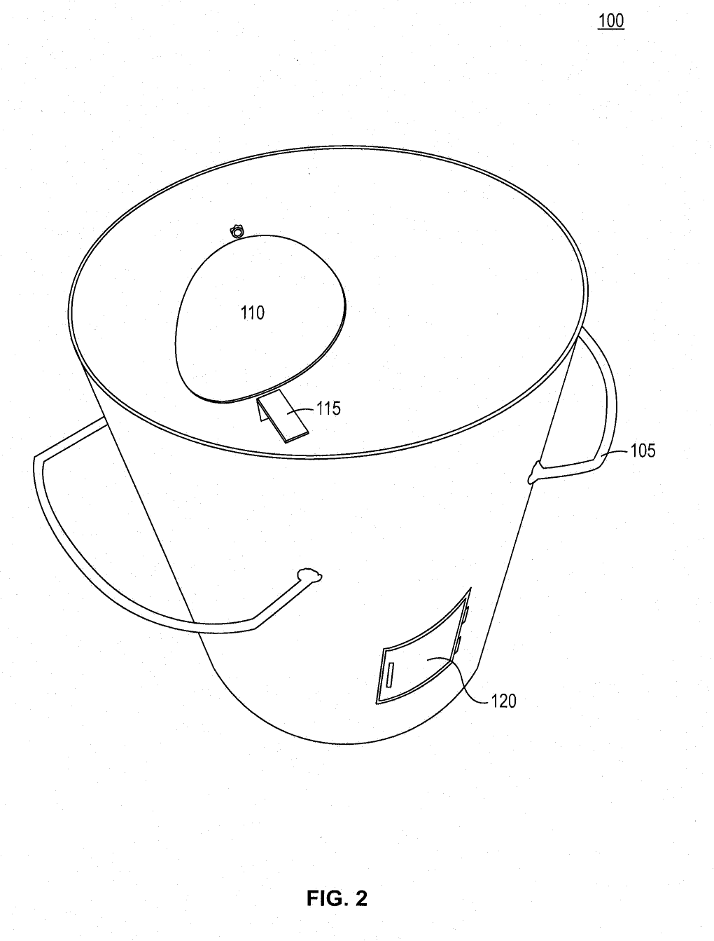

As illustrated in FIG. 1, the outer housing 100 contains an opening 110 configured to accommodate a TEG 400. Although opening 110 is illustrated as having a round shape, it is understood that the opening 110 preferably is configured to match the shape of the TEG 400, whatever that shape may be. The opening 110 should be no larger than necessary to accommodate the TEG 400 in order to minimize combustion heat loss. Optionally, the outer housing 100 also contains a TEG support 115 which is designed to provide structural stability to the various components when the TEG 400 is installed in the cooker 10. As illustrated in FIG. 2, the TEG support 115 may be an internal tab or shelf positioned below the opening 110 on which the TEG 400 rests.

In one embodiment, the outer housing 100 has a reversible closure for opening 110. The reversible closure may be a door, such as a hinged door affixed to the outer housing, or a removable panel and engaging mechanisms (e.g., slots and tabs) that effectively covers opening 110. The ability to seal opening 110 allows the cooker 10 to be used without a TEG 400 without excessive heat loss through opening 110 or air flow into the air gap 130. Optionally, the reversible closure also contains perforations, optionally with a further reversible closure, to allow the user to control air flow into air gap 130.

In another embodiment, the cooker 10 has an electric fan (i.e., instead of a TEG 400) positioned and mounted within opening 110. The fan may be used to create a positive pressure within air gap 130 by blowing ambient air into the cooker 10. This air is forced through the perforations 230 and improves the efficiency of combustion. The fan may be powered by any suitable means including, for example, a battery, a solar panel, or power from an electrical grid.

Optionally, the outer housing also contains a door 120 positioned at a level below the bottom of the fire basket 300 and is designed to provide access to an ash collection container 510. Optionally, the outer housing 100 also contains a plurality (three, four, five, six, or more) legs (not illustrated) designed to support the outer housing 100 above the ground.

Inner Housing

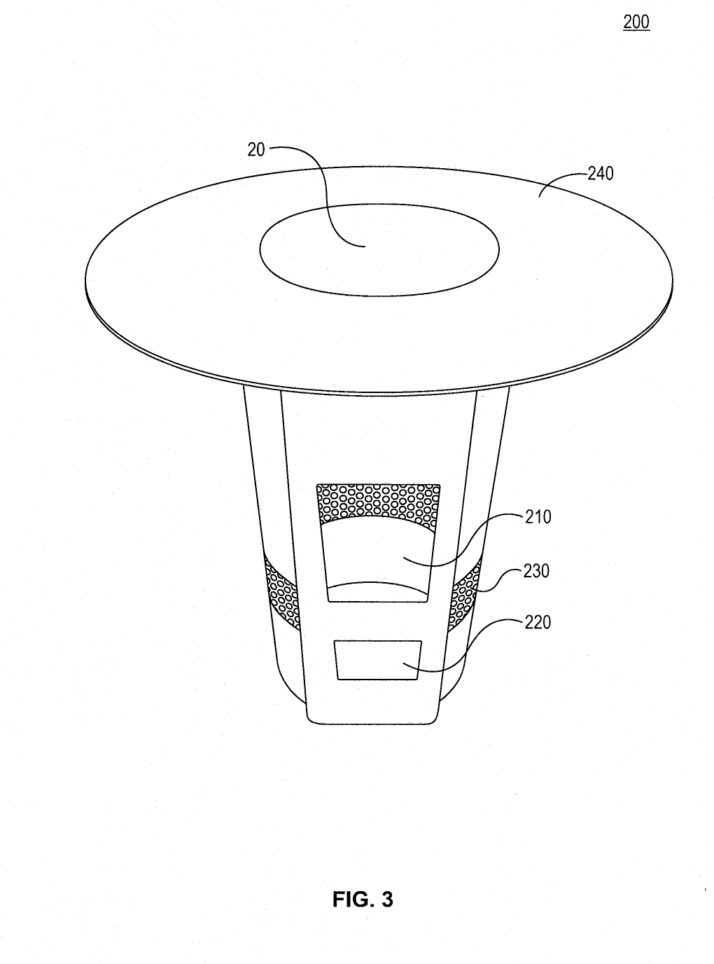

The body inner housing 200 is configured to fit within the outer housing 100 and provide an air gap 130 between the inner housing 200 and the outer housing 100. Preferably, the inner housing 200 has the same general shape as the outer housing 100. As illustrated in FIGS. 2 and 3, the inner housing 200 and outer housing 100 have a generally round shape, although the specific shape is not critical and these components may be differently-shaped but still function in accordance with the principles of the invention.

The inner housing 200 contains an opening 210 configured to accommodate the TEG 400 and align with opening 110 in the outer housing 100. Optionally, the outer housing 100 and the inner housing 200 have an alignment mechanism to assist in aligning opening 110 and 210. Optionally, the inner housing 200 also has opening 220 which aligns with door 120 to provide access to an ash collection container 510.

Optionally, the inner housing 200 also contains perforations 230 to facilitate airflow from the air gap 130 between the inner housing 200 and the outer housing 100 into the combustion chamber defined by the fire basket 300.

In one embodiment, opening 220 is positioned below the lowest level of the perforations 230, as illustrated in FIG. 3. Alternatively, opening 220 may be present within a perforated region.

Inner housing 200 is illustrated as having cooker top 240 as an integral member. In this configuration, inner housing 200 is used with an outer housing 100 that is open at the top such that the cooker 10 is defined on the lateral surfaces by the outer housing 100 and top surface by the cooker top 240. Thus, the bottom side of the cooker top 240 rests on the top edges of the outer housing 100 when the cooker 10 is assembled.

Fire Basket

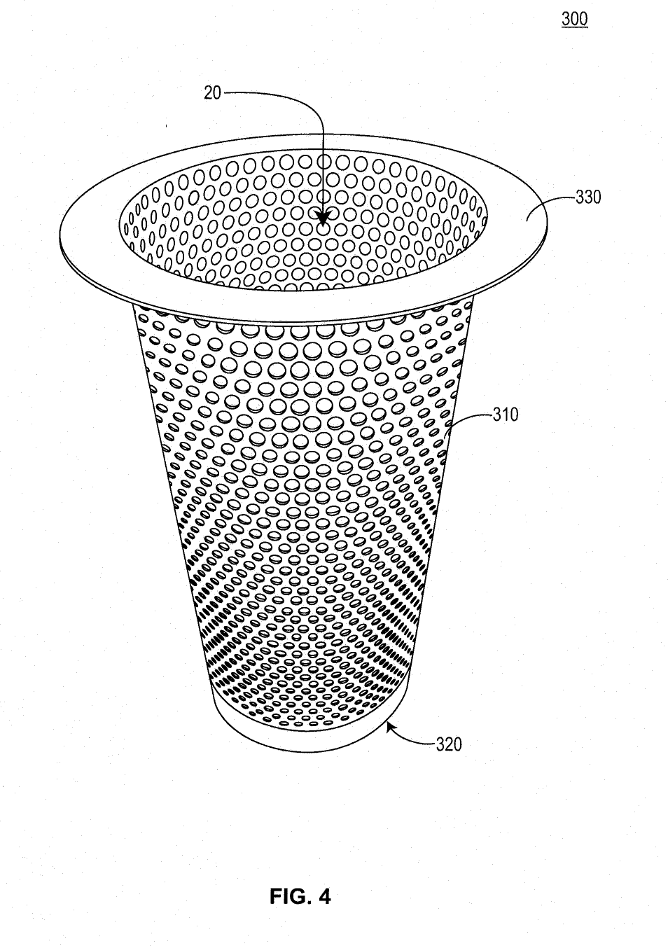

As illustrated in FIG. 4, the fire basket 300 defines the combustion chamber. The fire basket 300 is open at the top. The fire basket 300 is defined as having lateral sides 310 and a bottom 320, wherein lateral sides are perforated over their entire height and formed from a mesh material.

The fire basket 300 further contains a support mechanism for engaging the inner housing 200 and/or the outer housing 100. As illustrated in FIG. 4, the support mechanism is a flange 330 configured to rest on the top of the inner housing 200 and/or outer housing 100, or a support member within the inner housing 200.

Assembled Cooker Body

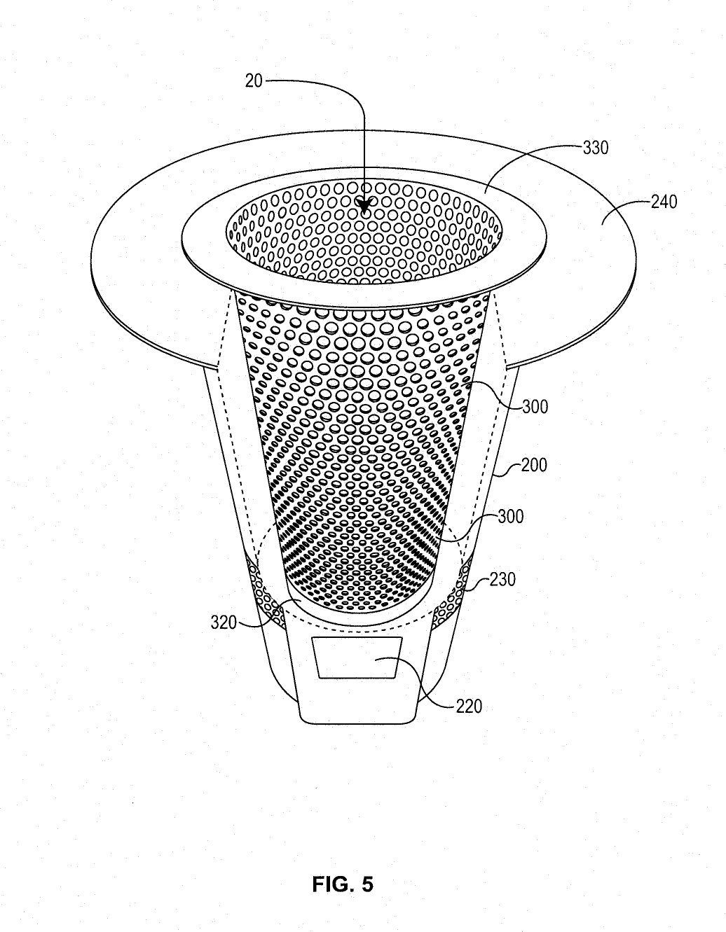

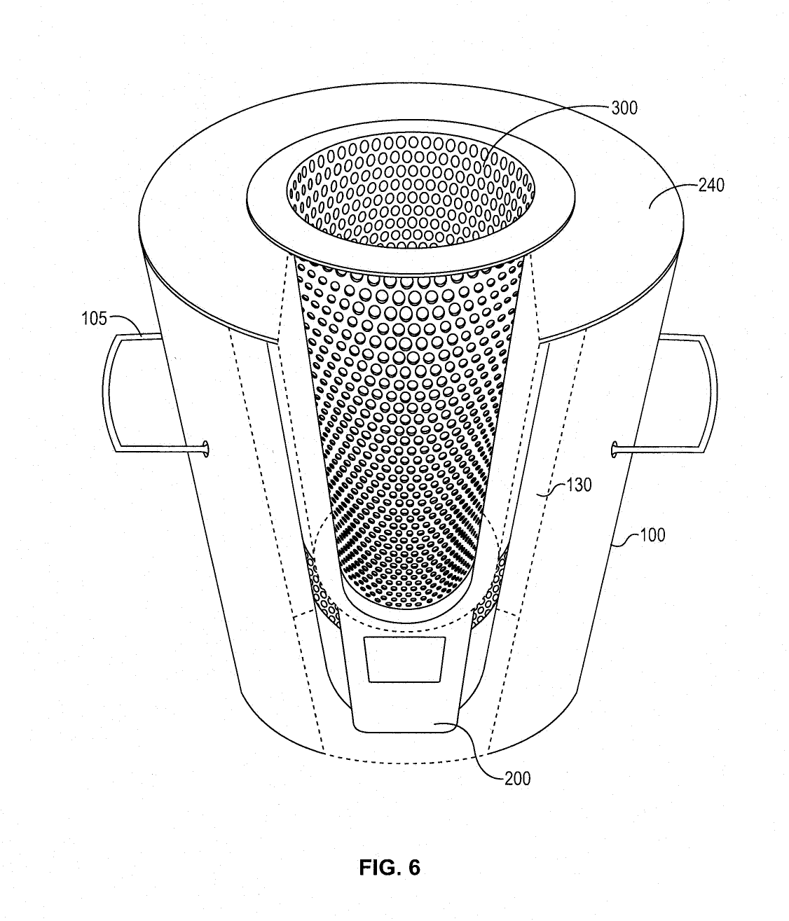

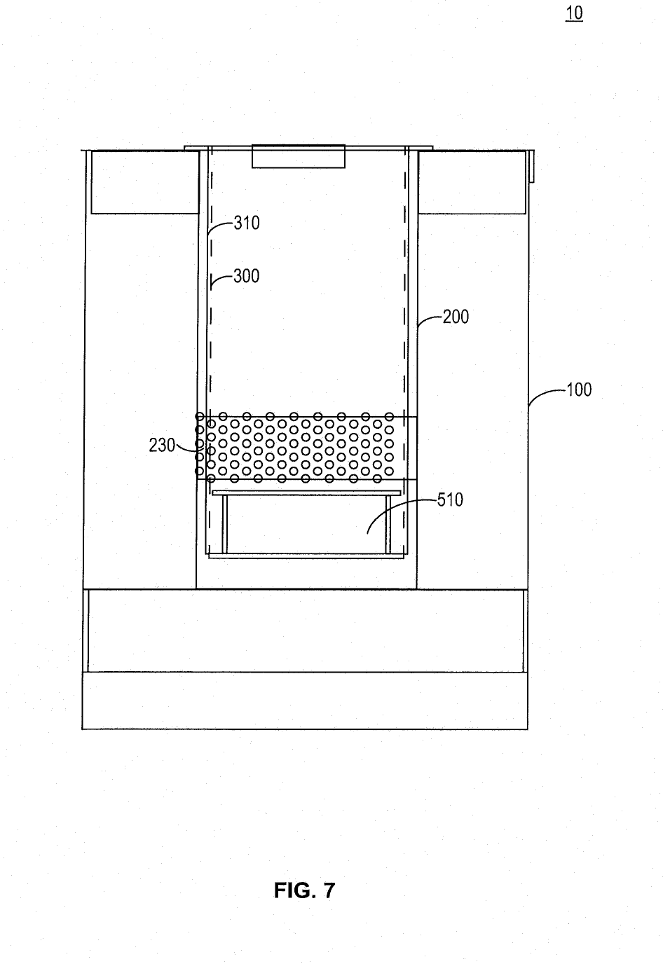

FIGS. 5 and 6 illustrate various aspects of an assembled cooker body. FIG. 5 illustrates the engagement of the fire basket 300 with the inner housing 200. Specifically, fire basket 300 is positioned within the central space defined by the inner housing 200, and the flange 330 of the fire basket 300 rests on the cooker top 240 of the inner housing 200. As illustrated in this embodiment, inner housing 200 has perforations 230 only at a level below the bottom 320 of the fire basket 300. The flange 330 defined the inner boundary of the chimney portion of the combustion chamber/fire basket 300. A cooking ring 15 (not illustrated) is designed to engage with the flange 330 in order to support a cooking vessel and allow for the venting of combustion gases and heat produced within the fire basket 300. Opening 220 is positioned below the perforations 230. In the embodiment illustrated, the region above opening 220 is not perforated in order to provide additional structural rigidity to the inner housing 200. Thus, the perforations 230 do not fully circumnavigate the inner housing 200. It is understood that this is a routine design choice and that other configurations are possible. For example, opening 220 may be disposed relatively lower on the inner housing 200 such that the perforations 230 fully circumnavigate the inner housing 200.

FIG. 6 illustrates a cross-section through a fully assembled cooker 10. The fire basket 300 is placed within the central space defined by the inner housing 200, as illustrated in FIG. 5, and the inner housing 200 assembly with the fire basket 300 is placed within the central space defined by the outer housing 100. As described previously, the inner housing 200 has a significantly smaller outer dimension than the inner dimension of the outer housing 100 to create an air gap 130 between the two. In the illustrated embodiment, the cooker top 240 is integral to the inner housing 200 and rests on the top edge of the outer housing 100 such that the inner housing 200 is supported above the bottom of the outer housing 100. As described previously, the outer housing 100 may be open at the bottom or may have a solid/continuous bottom or a discontinuous bottom.

Ash Collection Container

In some embodiments and as illustrated in FIG. 6, the cooker further comprises an ash collection container 510 positioned below the fire basket 300.

### EXAMPLE 2

### Cooker With Discontinuous Outer Housing And Multiple TEGs

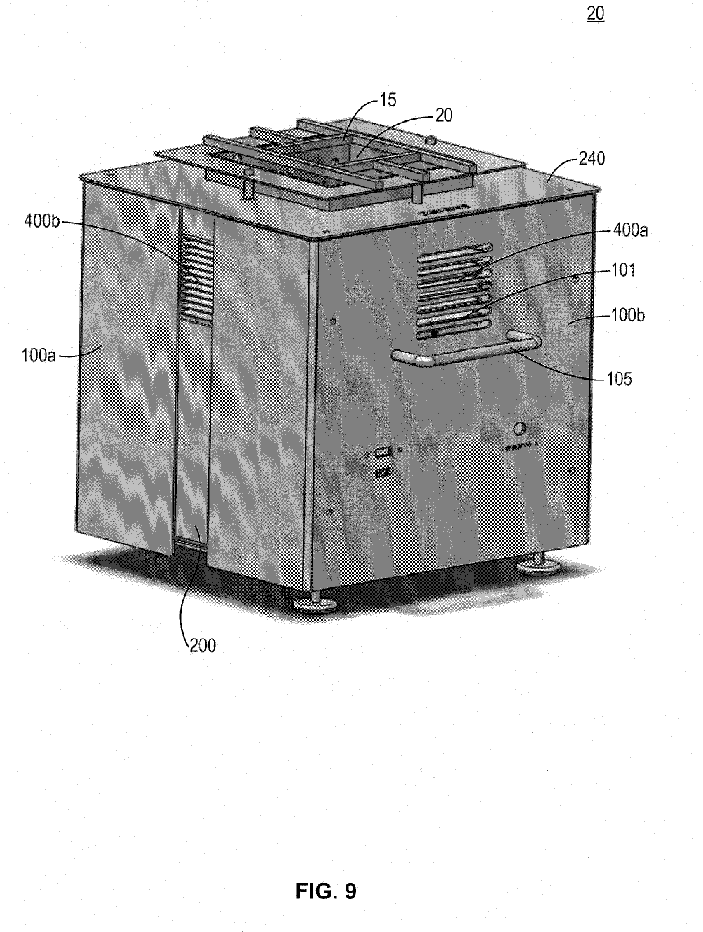

FIG. 9 is a perspective view of a fully assembled cooker 20 constructed in accordance with the principles of the invention. The cooker 20 is defined by a discontinuous outer housing having two panels 100a and 100b. The cooker 20 also contains two handles 105 disposed on opposite sides of the assembled cooker 20. In some embodiments, the two panels 100a and 100b are substantially identical to facilitate the ease of manufacture. Cooker 20 also contains an inner housing 200, cooker top 240, and cooking ring 15. Cooker 20 is illustrated as being substantially square or rectangular and having four TEGs 400; one on each side. Each outer housing panel 100a and 100b also contains a vent 101 to facilitate airflow over the cold side heat sink 410.

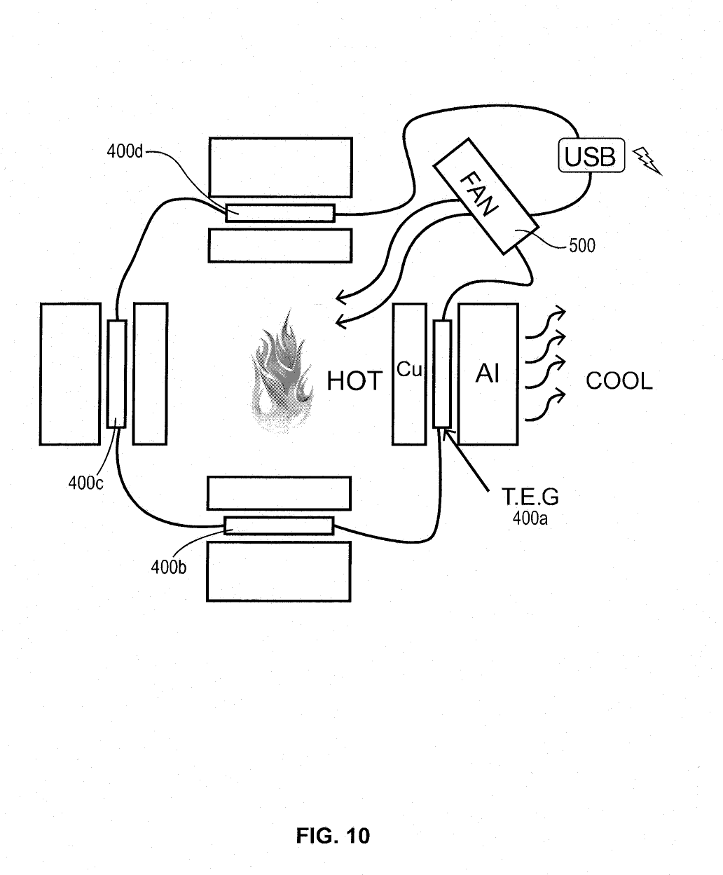

FIG. 10 is a schematic top-view of the assembled cooker illustrating the electrical wiring connection among the four TEGs 400a-d. In this case, copper (Cu) is used to thermally couple the hot side heat sink 420 of each TEG to the fire basket 300 (not shown). The cold side heat sink 410 comprises aluminum. Also illustrated is a fan 500 position to blow air into the fire basket. Fan 500 is powered from the TEGs. The system in FIG. 10 is illustrated as having a single electrical output socket, shown as a USB port. However, this configuration is not limiting. For example, each TEG may have one or more independent output ports. Furthermore, the plurality of TEGs need not be in an electrical connection such that each TEG operates independently.

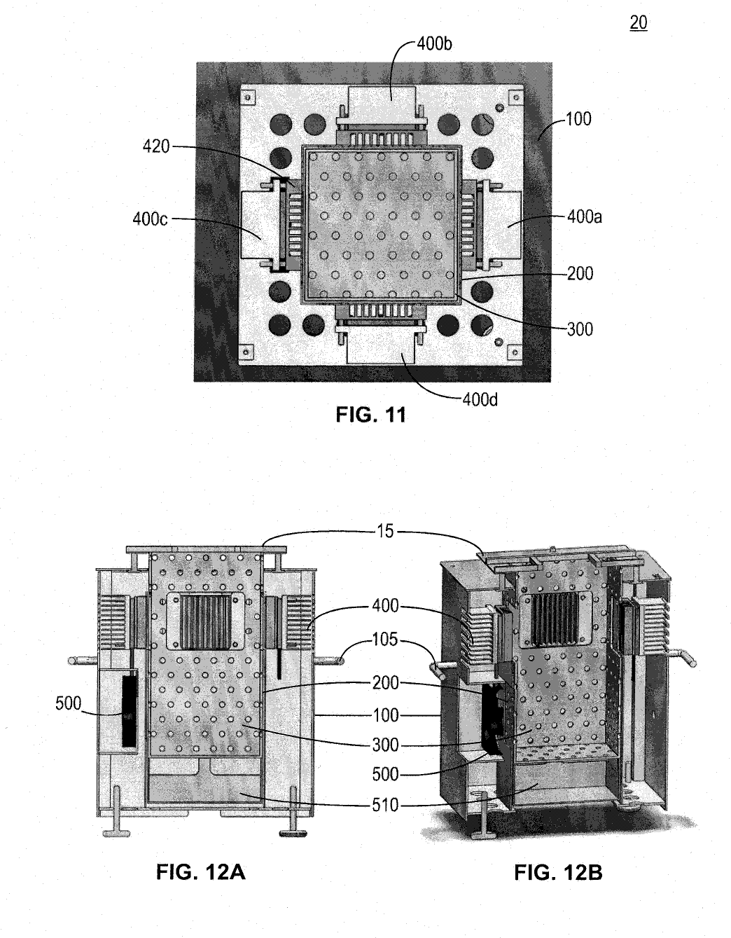

FIG. 11 is a top plan view of the assembled cooker 20. TEGs 400a-d are mounted on the inner housing 200 and the hot side heat sink 420 is in direct contact with fire basket 300

FIGS. 12A-B are cross-sectional views of the assembled cooker 20 illustrating the various components described above.

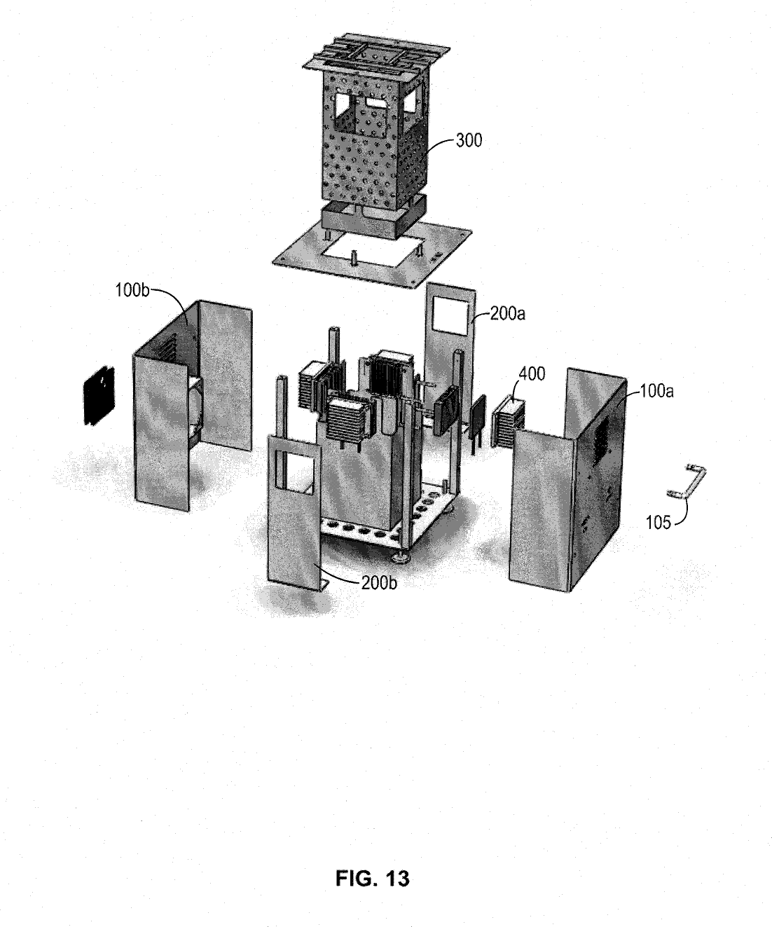

FIG. 13 is an exploded view of the assembled cooker 20 illustrating the various components described above.

It will be appreciated by persons having ordinary skill in the art that many variations, additions, modifications, and other applications may be made to what has been particularly shown and described herein by way of embodiments, without departing from the spirit or scope of the invention. Therefore it is intended that scope of the invention, as defined by the claims below, includes all foreseeable variations, additions, modifications or applications.

What is claimed is:

1. A thermoelectric generator, comprising:
a hot side heat sink being coupled with a periphery of a fire basket disposed within a housing; and
a cold side heat sink being coupled with said hot side heat sink and not extending outside of the housing.

2. The thermoelectric generator of claim 1, wherein the thermoelectric generator generates electrical power based upon a thermal differential between said hot side heat sink and said cold side heat sink.

3. The thermoelectric generator of claim 1, wherein said hot side heat sink is in direct thermal communication with the periphery of the fire basket.

4. The thermoelectric generator of claim 1, wherein said cold side heat sink is cooled via exterior air available outside the housing.

5. The thermoelectric generator of claim 1, wherein said hot side heat sink does not extend into a central combustion chamber formed within the fire basket.

6. A method for manufacturing a thermoelectric generator, comprising:
coupling a hot side heat sink with a periphery of a fire basket disposed within a housing; and
coupling a cold side heat sink with the hot side heat sink,
wherein the cold side heat sink does not extend outside of the housing.

7. The method of claim 6, further comprising enabling the thermoelectric generator to generate electrical power based upon a thermal differential between said hot side heat sink and said cold side heat sink.

8. The method of claim 6, wherein said coupling the hot side heat sink includes placing the hot side heat sink in direct thermal communication with the periphery of the fire basket.

9. The method of claim 6, further comprising enabling the cold side heat sink to be cooled via exterior air available outside the housing.

10. A combustion device, comprising:
a fire basket being disposed within a housing and defining a central combustion chamber; and
a thermoelectric generator being disposed at a periphery of said fire basket and comprising a cold side heat sink being cooled via exterior air available outside the housing and a hot side heat sink being in direct thermal communication with the periphery of said fire basket and not extending outside of the housing.

11. The combustion device of claim 10, wherein said thermoelectric generator generates electrical power based upon a thermal differential between the hot side heat sink and the cold side heat sink.

12. The combustion device of claim 10, wherein said thermoelectric generator comprises a plurality of thermoelectric generators being disposed about the periphery of said fire basket and comprising respective cold side heat sinks and respective hot side heat sinks.

13. The combustion device of claim 12, wherein the hot side heat sinks of said thermoelectric generators communicate with the central combustion chamber via respective openings formed in the periphery of said fire basket.

14. The combustion device of claim 10, wherein said thermoelectric generator extends between said fire basket and the housing, or wherein said fire basket is removably disposed within the housing.

15. The combustion device of claim 10, further comprising an electric fan for drawing the exterior air into the housing and onto the cold side heat sink of said thermoelectric generator.

16. The combustion device of claim 15, wherein said electric fan draws the exterior air from outside the housing into the combustion chamber, or wherein said thermoelectric generator provides the electrical power for operating said electric fan.

17. The combustion device of claim 15, wherein the housing comprises an inner housing for receiving said fire basket and an outer housing being disposed about said inner housing and defining an air gap therebetween, said electric fan drawing the exterior air from outside said outer housing into the air gap for cooling the cold side heat sink of said thermoelectric generator.

18. The combustion device of claim 10, wherein said fire basket includes a bottom region and a lateral region being coupled with the bottom region for defining the central combustion chamber.

19. The combustion device of claim 18, wherein said fire basket comprises a cooker top region being opposite the bottom region and defining a chimney opening in communication with the central combustion chamber.

20. The combustion device of claim 10, further comprising a power connector for coupling with a peripheral device and providing the electrical power generated by said thermoelectric generator to the coupled peripheral device.
